(19) United States
(12) Patent Application Publication
(10) Pub. No.: US 2021/0181285 A1
(43) Pub. Date: Jun. 17, 2021

(54) ARTIFACT REDUCTION IN SPIN-ECHO MR IMAGING OF THE CENTRAL NERVOUS SYSTEM

(71) Applicant: Siemens Healthcare GmbH, Erlangen (DE)

(72) Inventor: Alto Stemmer, Erlangen (DE)

(73) Assignee: Siemens Healthcare GmbH, Erlangen (DE)

(21) Appl. No.: 17/124,427

(22) Filed: Dec. 16, 2020

(30) Foreign Application Priority Data
Dec. 17, 2019 (EP) 19216974.6

(51) Int. Cl. G01R 33/483; G01R 33/561; G01R 33/565; G01R 33/563

(52) U.S. Cl. CPC G01R 33/4833; G01R 33/563; G01R 33/56545; G01R 33/5617

(57) ABSTRACT

In a method for activating a magnetic resonance imaging (MRI) system for generating MRI data relating to an examination subject, in which system raw magnetic resonance (MR) data is captured, having at least one spin echo or turbo spin echo pulse sequence: a radio frequency (RF) excitation pulse is emitted to excite a region that contains a region to be imaged, the excited region being defined by a selection gradient; an RF refocusing pulse is emitted to influence a refocusing region, the refocusing region at least partly including the region to be imaged, and being defined by at least one selection gradient; and high-frequency (HF) signals are received to acquire raw MR data. A spatial extent of the excitation region is selected to be different (e.g. significantly different) from a spatial extent of the refocusing region.

### CROSS REFERENCE TO RELATED APPLICATIONS

This patent application claims priority to European Patent Application No. 19216974.6, filed Dec. 17, 2019, which is incorporated herein by reference in its entirety.

### BACKGROUND

### Field

The disclosure relates to a method for activating a magnetic resonance imaging (MRI) system for generating magnetic resonance imaging data relating to an examination subject, in which raw magnetic resonance data is acquired. The disclosure further relates to an activation sequence to activate a magnetic resonance imaging system. The disclosure finally relates to a magnetic resonance imaging system.

### Related Art

When generating magnetic resonance (MR) images, the body to be examined is exposed to a relatively high main magnetic field, for example, of 1.5 Tesla, 3 Tesla or in more modern high magnetic field facilities even of 7 Tesla and higher. A high-frequency excitation signal is then transmitted using an appropriate antenna device, which leads to the nuclear spins of certain atoms that have been resonantly excited in the given magnetic field by this high-frequency field being tilted around a defined flip angle with respect to the magnetic field lines of the main magnetic field. The high-frequency (HF) signal known as the magnetic resonance signal, which is emitted during the relaxation of the nuclear spins, is then received by means of appropriate antenna devices, which can also be identical to the transmitter facility. After demodulation and digitization, the raw data thus acquired is ultimately used to reconstruct the desired image data. For the spatial encoding, defined magnetic field gradients are superimposed respectively on the main magnetic field during transmission and readout or receiving of the high-frequency signals and in the intervals between transmission and receiving or receiving and retransmitting.

A magnetic resonance image is usually made up of a large number of individual partial measurements, in which raw data is recorded from various slices of the examination subject in order to reconstruct volume image data therefrom. One use of MR imaging relates to the imaging of the spinal column. Flowing through the spinal cord in the spinal column is a fluid known as cerebrospinal fluid (abbreviated to CSF). This fluid is colorless, is connected to the brain tissue fluid and has a very similar composition. This fluid is produced by specific epithelial cells in the network of veins in the ventricles of the brain. The constant fresh supply of cerebrospinal fluid is drained via the spinal cord into the lymphatic system, where it gets broken down. CSF has a long T1 relaxation time and a long T2 relaxation time. The T1 relaxation time shall be defined as usual as the relaxation time for the longitudinal magnetization in the z-direction, that is, in the direction of the main magnetic field. A T2 relaxation time shall be defined as usual as the relaxation of the transverse magnetization. Now, if for example, a two-dimensional axial T2-weighted imaging of the spinal column is carried out with a 2D-turbo spin echo pulse sequence, the CSF shows up very clearly due to the long T2 relaxation time. Due to the motion of the CSF with the rhythm of the heartbeat, artifacts are created, rendering interpretation of the diagnostic images more difficult. The physical cause of the flow artifacts is described for instance in the article “Normal MRI Appearance and Motion-Related Phenomena of CSF” by Christopher Lisanti et al., published in AJR: 188, March 2007, pages 716-725. The article describes a plurality of causes. The present disclosure addresses the phenomenon described in the article as “time-of-flight (TOF) loss”. The cause of “time-of-flight (TOF) loss” is that flowing or pulsating CSF, which at the time of excitation was in the respectively excited and refocused slice, leaves the slice in the time between excitation and refocusing, and hence fails to be refocused and consequently therefore fails to provide a signal portion in the echoes that are subsequently generated. Fresh CSF flowing into the slice has in turn not “seen” the excitation pulse and accordingly also fails to provide a signal portion. A turbo spin echo sequence consists of an RF excitation pulse and a series of refocusing pulses that generate a plurality of echoes. Each echo is typically spatially encoded in a different way with the aid of phase-encoding and frequency-encoding gradients, such that, for example, a plurality of k-space lines can be read out after one excitation pulse. A 2-dimensional turbo spin echo sequence is understood here to be a turbo spin echo sequence in which the phase encoding only occurs in one spatial direction that is perpendicular to the frequency encoding and perpendicular to the slice selection direction. In a 3-dimensional turbo spin echo sequence, the phase encoding typically ensues additionally in the slice selection direction. When a 2-dimensional turbo spin echo sequence is used, the volume to be examined is typically acquired in slices. The width, number and distance between the individual slices is typically predetermined by the user.

FIG. 1 shows a conventional 2D-turbo spin echo pulse sequence with which MR imaging of the spinal cord can be carried out. There are indeed other T2-weighted imaging methods that are more robust with respect to flow phenomena, but these in turn have other disadvantages and are therefore not clinically acceptable, at least not for all radiologists. One example of such an alternative imaging method is the three-dimensional T2-weighted turbo spin echo pulse sequence. In such an imaging method, non-selective refocusing RF-pulses are used, with which the entire volume is imaged instead of one slice.

As a result thereof, with 3D-imaging as compared with 2D-imaging, the contrast between the various tissue components is reduced. In order to achieve with 3D-technology a running time that is of the same magnitude as an equivalent 2D-measurement with equivalent resolution, further sequence parameters have to be changed in comparison with 2D-imaging, however.

For example, the echo train length, that is, the number of refocusing-RF pulses per excitation, has to be increased.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is a sequence diagram showing a conventional flow-compensated 2D-turbo spin echo sequence.

FIG. 2 is a sequence diagram showing the “time of flight loss” effect according to exemplary embodiments.

FIG. 3 is a sequence diagram showing a pulse sequence for an MR imaging method according to exemplary embodiments.

FIG. 4 is a sequence diagram showing a pulse sequence for an MR imaging method according to exemplary embodiments.

FIG. 5 is a diagram of a sinc-function of an RF pulse according to exemplary embodiments.

FIG. 6 is a simulation of a flow-compensated turbo spin echo pulse sequence with a broadening factor of the refocusing—pulse of 3 by means of a decreasing slice selection gradient, according to exemplary embodiments.

FIG. 7 is a simulation of a flow-compensated turbo spin echo pulse sequence with a broadening factor of the refocusing pulse of 3 by means of an increasing bandwidth-time product, according to exemplary embodiments.

FIG. 8 is a flowchart of a method for activating a magnetic resonance imaging system, according to exemplary embodiments, for generating magnetic resonance imaging data relating to an examination subject, in which raw magnetic resonance data is captured.

FIG. 9 is a magnetic resonance imaging (MRI) system according to exemplary embodiments.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

The object is therefore to reduce the artifacts that occur in the MR-imaging of the spinal cord with the aid of 2D spin echo pulse sequences, in order to improve the image quality and therefore make a diagnosis based on the image easier.

The method according to the disclosure for activating a magnetic resonance imaging system for generating magnetic resonance imaging data relating to an examination subject, in which raw magnetic resonance data is acquired, includes the running of at least one spin echo pulse sequence or one turbo spin echo pulse sequence. In this context, the method has an excitation process. In the excitation process, an RF excitation pulse is emitted, with which a region that includes a region to be imaged is excited, and the excited region is defined by at least one first selection gradient. Part of the method also involves a refocusing step, in which a RF refocusing pulse is emitted, with which a refocusing region is influenced. The refocusing region is defined by at least one second selection gradient. The refocusing region includes in turn the region to be imaged. If a one-dimensional selection is carried out to define the region to be selected, then this is referred to as a slice selection gradient for setting the width of the slice. Variants with a two-dimensional selection are also possible, however, in which selection gradients are applied in two spatial directions, for example, while RF-pulses are radiated.

In the context of the excitation step and of the refocusing step, the spatial extent of the excitation region is selected to be significantly different from the spatial extent of the refocusing region. “Significantly different” shall mean in this context that the ratio of the extent of the larger region and of the smaller region is clearly more than the value 1.2, and preferably more than 1.5.

The value 1.2 is not to be confused with the lowering of the amplitude of the slice selection gradient of the refocusing RF pulse that is traditionally used when utilizing identical SINC pulses for the excitation and refocusing compared with the amplitude of the slice selection gradient of the RF excitation pulse. The lowering of the amplitude is connected with the fact that traditionally when using identical SINC pulses for the excitation and refocusing, as a result of the higher flip angle, the slice profile of the refocusing RF pulse is already contracted compared with the slice profile of the excitation pulse. In order to compensate for this, the amplitude of the slice selection gradient of the refocusing-RF pulse is traditionally reduced compared with the amplitude of the slice selection gradient of the excitation RF pulse, by the factor 1.2, for example.

Furthermore, the method comprises a readout step for the acquisition of raw magnetic resonance data. The readout step comprises in particular the receiving of HF signals, which are triggered by the processes described in the aforementioned.

The activation sequence according to the disclosure for activating a magnetic resonance imaging system has an RF excitation pulse with which a region that includes a region to be imaged is excited. Furthermore, the activation sequence comprises at least one selection gradient, by means of which the width of the excited region is defined. Here, a selection gradient is understood as a gradient that is applied during the irradiation of the RF pulse. The excited region can include in particular a slice that is to be imaged. In this case, the selection gradient that defines the slice to be imaged is a slice selection gradient. Part of the activation sequence is also an RF refocusing pulse, with which a refocusing region is influenced. The refocusing region is also defined by a selection gradient and likewise comprises the region to be imaged.

The refocusing region can include in particular a slice that is to be refocused. In this case, the selection gradient that defines the refocusing slice is a slice selection gradient.

The aforementioned RF pulses and selection gradients are coordinated with one another such that the spatial extent of the excitation region in the selection direction is significantly different from the spatial extent of the refocusing region in the selection direction. As already mentioned, this should be understood to mean that the ratio of the extent of the larger region and of the smaller region is clearly more than the value 1.2, and preferably more than 1.5. Finally, the activation sequence also includes a readout module for the acquisition of raw magnetic resonance data. The activation sequence according to the disclosure shares the advantages of the method according to the disclosure.

The magnetic resonance imaging system according to the disclosure comprises a controller, which is embodied to control the magnetic resonance imaging system using the method according to the disclosure. The magnetic resonance imaging system according to the disclosure shares the advantages of the method according to the disclosure.

The essential components of the controller according to the disclosure can be embodied mainly in the form of software components. However, these components can basically also be partly constructed in the form of software-supported hardware, for instance FPGAs or suchlike, in particular when particularly quick calculations are involved. Likewise, the necessary interfaces between individual functional components can also be embodied as software interfaces, for example when all that is involved is a transfer of data from other software components. However, these interfaces can also be embodied as interfaces constructed as hardware, which are activated by appropriate software.

A predominantly software-based implementation has the advantage that even controllers or activation sequence-determination devices already used hitherto can be upgraded in a simple manner by means of a software update so that they then operate in the manner according to the disclosure. To this extent, the object is also achieved by a corresponding computer program product comprising a computer program, which can be loaded directly into a memory facility of a controller of a magnetic resonance imaging system, with program segments to carry out all the steps in the method according to the disclosure when the program is run in the controller. Such a computer program product can optionally include additional components alongside the computer program, such as, for example, documentation and/or additional components and also hardware components, such as, for example, hardware keys (dongles etc.) for using the software.

For transfer to the controller of the magnetic resonance imaging system and/or for storage on or in the controller a computer-readable medium can be used, for example, a memory stick, a hard disk or another transportable or fixedly installed data-carrier, on which are stored program segments of the computer program that can be imported and executed by a computation unit of the controller. For this purpose, the computation unit can comprise, for example, one or a plurality of collaborating microprocessors or suchlike.

A predominantly software-based implementation has the advantage that even controllers of magnetic resonance systems can be upgraded in a simple manner by means of a software update so that they then operate in the manner according to the disclosure. To this extent, the object is also achieved by a computer program which can be loaded directly into a memory facility of a magnetic resonance system, with program segments to carry out all the steps in the method according to the disclosure when the program is run in the magnetic resonance system.

In the context of the disclosure, the various features of different exemplary embodiments can also be combined into new exemplary embodiments.

In one embodiment of the method according to the disclosure, the extent of the refocusing region in the selection direction is selected to be greater than the extent of the excitation region. In this advantageous variant, therefore, a larger refocusing region that includes the excitation region is selected. Advantageously, in this embodiment, spins whose carriers have already left the excitation region after excitation, that is chronologically between excitation and refocusing or between first and further refocusing steps, but are still located in the further extended refocusing region are also captured. These spins too now provide one signal portion, which contributes to an improvement in image quality. This variant is particularly suitable for use in a turbo spin echo sequence. In a turbo spin echo sequence, refocusing is repeated a number of times. If the dimensions of the refocusing region are large enough, then the excited spins in the CSF still remain in the refocusing region after a plurality of echoes. As a result there is effective compensation for the formation of artifacts.

A spin echo sequence is understood here to mean a sequence whereby after each excitation pulse a refocusing RF pulse is applied in order to form a spin echo in each case. Different k-space lines are therefore acquired after different excitations. In an alternative embodiment of the method according to the disclosure, for the event of a spin echo sequence, the extent of the excitation region is selected to be greater than the extent of the refocusing region. It is assumed that the excitation region spatially encloses the refocusing region. Furthermore, the width of the refocusing region is determined by the slice thickness desired by the user. In this embodiment more spins than necessary are excited as a precautionary measure. Some CSF spins do indeed leave the later refocusing region after an excitation, but they are replaced by excited spins that are still located outside the later refocusing region at the time of excitation, but flow into the refocusing region during the time between excitation and refocusing. In this way the image signal is improved compared with a scenario in which the excitation region and the refocusing region have equal dimensions.

In a slice-selective variant of the method according to the disclosure, the region to be imaged includes an excitation slice, which is defined by a slice selection gradient, and the refocusing region includes a refocusing slice, which is defined by a slice selection gradient. Here the spatial slice thickness of the excitation slice is significantly different from the slice thickness of the refocusing slice.

In the slice-selective variant, the refocusing slice can be selected to be thicker than the excitation slice. Here the refocusing slice at least partly and preferably completely includes the excitation slice. The inventive method is particularly advantageous when the direction of motion of the CSF spins substantially concurs with the slice selection direction, and therefore is substantially perpendicular to the slice plane. In this case, as a result of the broadening of the refocusing slice compared with the excitation slice, CSF-spins that leave the excitation slice after excitation but still remain in the refocusing slice during refocusing are also acquired in the imaging. Such a procedure is particularly suitable for the 2D turbo spin echo sequence.

Alternatively, for the specific case of a 2D spin echo sequence, the excitation slice can be selected to be thicker than the refocusing slice, it being in turn advantageous if the CSF spins move in the direction of the slice thickness. If the thicker excitation slice includes the refocusing slice, then CSF spins that have not yet resided in the later refocusing slice during excitation, move into the refocusing slice during the time between excitation and refocusing and replace excited CSF spins which have left the refocusing slice in this interim period. Only spins that have been recorded by both RF pulses contribute to the signal. In this way, the “time-of-flight loss” effect is therefore likewise compensated for.

In a method according to an exemplary embodiment of the disclosure, the thickness of the thinner of the two slices is equal to a slice thickness specified by the user. In this variant, the thickness of the thinner of the two slices is selected in the slice selection direction according to the desired resolution. Advantageously, the resolution of static tissue components is not impaired by this. If on the other hand, the excitation and refocusing slice is broadened, as suggested in the literature in order to reduce the “time-of-flight loss” effect, then as the slice thickness increases, the resolution of static tissue in the slice selection direction also deteriorates.

It is particularly advantageous, if in the method according to the disclosure, the pulse parameters of the excitation pulse or of the refocusing RF pulse are selected such that the slice selection gradients of the two RF pulses have approximately the same amplitude. This makes it possible, in the event of local off-resonance, for the excitation and refocusing slice to be equally curved and this avoids the occurrence of a partial or total signal loss due to a lack of overlap of the excited and the refocused slice. A local off-resonance is understood here to mean a local deviation from the ideally constant B₀-field, for example as a result of susceptibility effects.

In a particularly effective variant of the method according to the disclosure, the pulse parameters of the broader RF pulse are adjusted such that the slice selection gradients of both RF pulses have approximately the same amplitude.

In an alternative embodiment of the method according to the disclosure, a gradient scheme is selected in the slice selection direction, the first moment of which has the value zero chronologically in the middle of the refocusing RF pulses.

The n^{th} moment mₙ(t) of a gradient array Gᵢ is understood to mean the integral

$${m}_{n} ( t ) = {\int }_{0}^{t} {G}_{i} ( τ ) \cdot {τ}^{n} d τ . \qquad ( 1 )$$

For the phase of a small sample that at the time 0 (middle of the excitation pulse) is located at the location r₀ and moves at a constant velocity v₀ through the measured volume, this gives:

$$φ ( t ) = 2 π γ {\int }_{0}^{t} \vec{G} ( τ ) \vec{r} ( τ ) d τ = 2 π γ {\int }_{0}^{t} \vec{G} ( τ ) [ {\vec{r}}_{0} + {\vec{v}}_{o} ( τ ) ] d τ = 2 πγ [ {\vec{m}}_{0} {\vec{r}}_{0} + {\vec{m}}_{1} {\vec{v}}_{0} ] \qquad ( 2 )$$

Spins that have moved therefore acquire an additional phase φ that is proportional to their velocity v₀ and to the first moment in the gradient array G.

The signal in the turbo spin echo-imaging consists of the second echo on of a superimposition of different signal components that start out with spins that follow different signal pathways. If a smooth-flowing spin follows a signal pathway that contains stimulated echoes, then its magnetization is stored during a number of echo intervals in the longitudinal direction. During this time it is not influenced by the gradients applied and therefore does not acquire any additional phase as a result of the motion. The precondition for the signal from smooth-flowing spins that follow different echo pathways being constructively added is that the net phase that is acquired within an echo interval (or the net phase that is acquired between two refocusing RF pulses) is zero. This is achieved by means of a gradient scheme the first moment of which in the middle of the refocusing RF pulses is zero.

In one embodiment of the method according to the disclosure, a gradient scheme is selected, the first moment of which at the time of the refocusing RF pulses is zero. This ensures that no additional phase is acquired as a result of the motion between any two refocusing RF pulses. This is, as has just been set out in detail, a necessary precondition for echo pathways that contain a different number of stimulated echoes and spin-echoes to be consistently superimposed.

If the velocity of the different spins that contribute to the signal for a voxel and hence for a pixel differs, then the additional phase φ, which is acquired as a result of the motion between the refocusing RF pulse and the echo, can lead to dephasing of the signal and hence to obliterations in the calculated images.

In a further embodiment of the method according to the disclosure, a gradient scheme is therefore selected in the slice selection direction, the first gradient moment of which additionally has the value zero at the time of the echoes (that is during the readout interval). The described dephasing of the signal is therefore reduced and thus counteracts a signal reduction or signal effacement.

In a particularly effective embodiment of the method according to the disclosure, a nested acquisition scheme is used in the acquisition of the individual slices. This approach ensues in order to avoid crosstalk or overlap of individual slices. In such a nested acquisition scheme, slices to be acquired are subdivided into sub-sets. The sub-sets are then captured successively. For example, a first sub-set includes only the even-numbered slices and a second sub-set includes only the odd-numbered slices. Here, the numbering of the individual slices corresponds to their anatomical position. In other words, the slice number of a slice is increased or decreased by the value 1 in relation to the slice directly spatially adjacent thereto. Therefore, through the subdivision into sub-sets, the interval between slices that are to be excited and read out successively is increased, by which means crosstalk or overlap of slices that are to be read out successively can be avoided in particular as a result of the broadened refocusing or excitation slice according to the disclosure. Subdivisions into more than two sub-sets are also possible in order to further enlarge the effective slice interval and hence avoid the risk of an overlap of slices that are read out in a directly successive order or of crosstalk and of image artifacts related thereto. A typical value when using the method according to the disclosure in imaging with turbo spin echo sequences is the broadening of the refocusing region by a factor of three compared with the slice thickness d specified by the user. Insofar as the slice interval of the set of slices is short compared with the specified slice thickness d, the batch of slices should then be measured in at least four data sub-sets in order to avoid crosstalk.

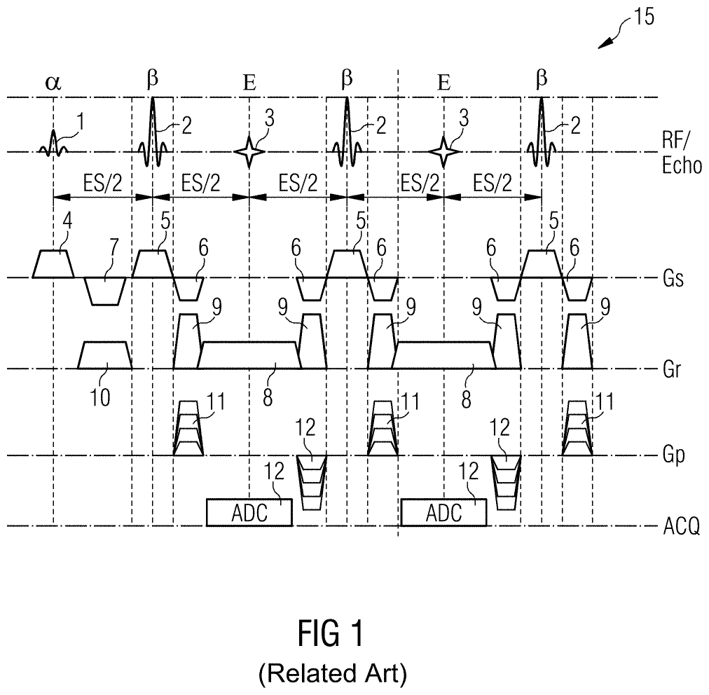

FIG. 1 shows a conventional flow-compensated 2D-turbo spin echo pulse sequence in a sequence diagram 15. The sequence diagram 15 comprises a total of five lines, with the first line being denoted by RF/echo and reproducing the “RF pulses” 1, 2, and the echoes thereof 3, emitted in accordance with the 2D-turbo spin echo pulse sequence. Above the first RF pulse 1 is the Greek letter α. The letter α is intended to symbolize that the first RF pulse 1 is what is known as an excitation pulse. Above the second RF pulse 2 is the Greek letter β, which is intended to symbolize that the second pulse is what is known as a refocusing pulse. Above the echoes 3, the Latin letter E is shown, which is intended to symbolize that these are echoes. In the second line, which is denoted by Gs, gradients 4, 5, 6, and 7 are shown in the slice-selection direction. In the third line, which is denoted by Gr, gradients 8, 9, and 10, which are applied in the readout direction, are illustrated. In the fourth line, which is denoted by Gp, gradients 11, 12, which are applied in the phase encoding direction, are shown. In the fifth line, which is marked ACQ, readout windows ADC are shown, that is, the time windows 12, in which measured data is acquired.

Such a 2D turbo spin echo sequence includes a 90° excitation pulse 1, which initially tilts the magnetization in a slice in the examination region into the transverse plane. The excitation pulse 1 is followed in a time interval of a half-echo time ES/2 by a first refocusing RF pulse 2. The echo time ES, also referred to as the echo interval, is a characteristic time constant in the sequence. It indicates the time between the individual echo signals 3. The first refocusing RF pulse 2 is followed within the turbo spin echo sequence by further refocusing RF pulses 2 with a respective time interval ES between one another. Moreover, a gradient 4, 5 is applied in two-dimensional imaging, synchronous with the excitation pulse 1 and the refocusing RF pulse 2, the amplitude of which gradient is adjusted to the respective spectral bandwidth of the RF pulse 1, 2 such that, perpendicular to the gradient, a one-dimensionally restricted slice of a desired thickness d is excited or refocused. The thickness d is typically understood to mean the width of the excitation profile up to the point where the excitation signal still amounts to only half of its maximum amplitude. The respective excited and refocused slice can be moved in the direction of the slice selection gradient 4, 5 by an appropriate selection of the RF mid-frequency, also referred to as the carrier frequency. For the readout, an echo signal 3 is captured in the chronological middle of two successive refocusing RF pulses 2. This echo signal 3 is typically frequency-encoded with a selection gradient 8 and a phase is imprinted on the echo signal 3 with the aid of a phase-encoding gradient 11. The imprinted phase is then shifted between the individual echo signals such that an MR image of the slice can be calculated from all readout echoes 3. Here, the readout gradient 8 and the phase encoding gradient 11 are applied orthogonal to each other and orthogonal to the slice selection gradient 4, 5. Then a phase-rephasing gradient 12 is applied in order to turn back the phase again between the readout interval and the next refocusing RF pulse 5. With the aid of a pair of what are known as crusher gradients 9, which are applied directly before and after the refocusing RF pulses 2, the provision of a signal portion by spins newly tilted into the transverse plane by the refocusing RF pulse 2 is avoided. The reason for the time-of-flight loss is that flowing or pulsating CSF, which at the time of excitation was in the respectively excited and later refocused slice, leaves this slice in the time between excitation and refocusing, and hence fails to be refocused and consequently therefore does not provide a signal portion in the echoes that are subsequently generated. Fresh CSF flowing into the slice has in turn not been captured by the excitation pulse and accordingly likewise does not provide a signal portion.

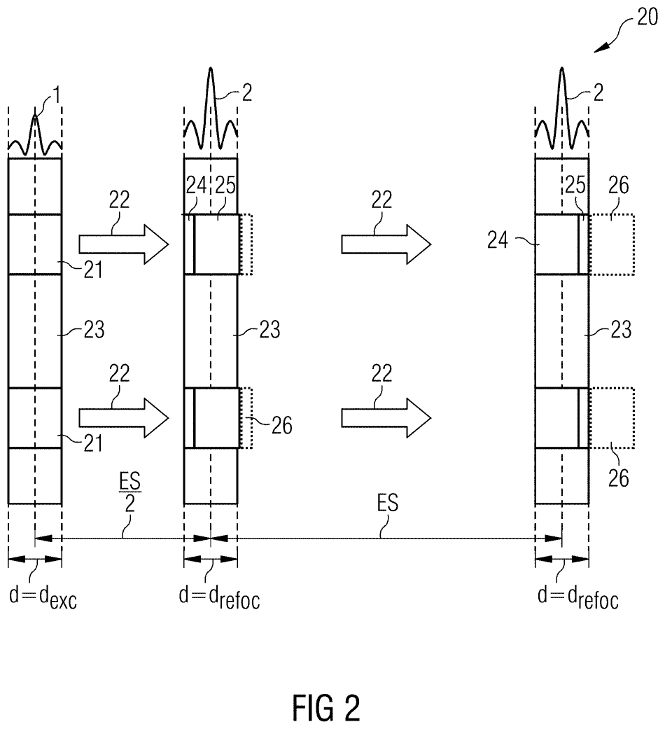

FIG. 2 shows a sequence diagram 20 with a pulse sequence, the use of which leads to image artifacts, based on what is known as the “time of flight loss” effect. FIG. 2 shows on the left a slice having the thickness d at the time of slice excitation. In the simplified view, both static spins 23 of the spinal cord and also dynamic CSF spins 21, which at the time of excitation are located in the slice with the thickness d, are excited, that is, tilted into the transverse plane. The horizontal arrows 22 in FIG. 2 are intended to show the flow of the cerebrospinal fluid between excitation and refocusing or between the two refocusing steps. In the center, FIG. 2 shows the same slice at a time of the first refocusing RF pulse that is half an echo t interval ES/2 later. In the sequence shown, the nominal thickness of the slice d_{refoc}, which is captured by the refocusing RF pulse, is selected in the prior art to be equal to the thickness of the excitation slice d_{exc} (d_{exc}=d_{refoc}=d). The static spins 23 in the spinal cord, which were located at the time of excitation in the slice under observation, continue to be located in the slice that has been captured and are completely refocused, such that they transmit a signal portion for the first and the further formatted echoes. A portion 26 of the flowing CSF spins, which were located at the time of excitation in the slice under observation, leave the slice again in the time between excitation and refocusing. This portion is not captured by the refocusing RF pulse and therefore does not transmit any signal portion in the echoes that are later refocused. The outgoing CSF spins 24 are replaced by CSF spins 24 that at the time of excitation were not located in the slice under observation and due to the lack of excitation likewise do not transmit any signal portion. On the right hand side, FIG. 2 shows the same slice at the time of the second refocusing RF pulse 2, that is, a time interval ES after the first refocusing RF pulse 2. As the time between excitation and refocusing increases, there is a rise in the percentage of CSF spins 26 that leave the slice, and a decrease in the percentage 25 of CSF spins that provide a signal portion to the focused echoes.

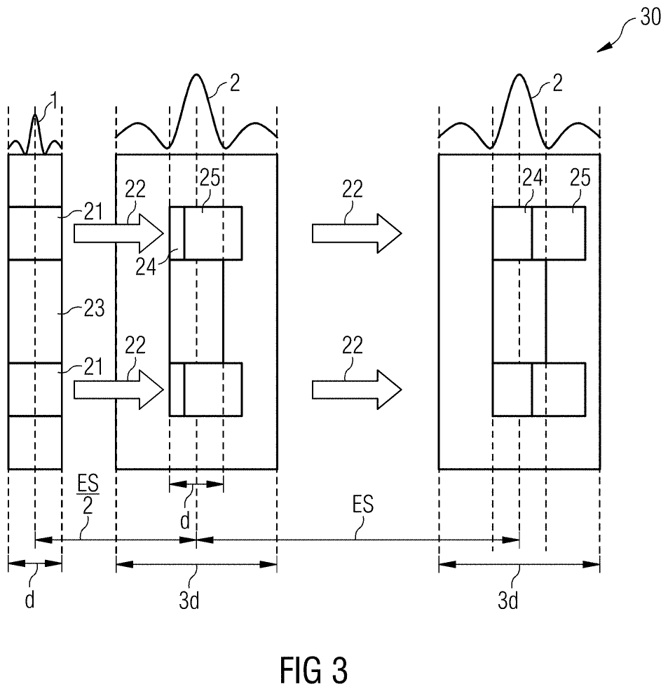

FIG. 3 illustrates a pulse sequence 30 for an MR imaging method according to a first exemplary embodiment of the disclosure. The pulse sequence illustrated in FIG. 3 allows the avoidance of or reduction of image artifacts due to the “time of flight loss” effect. On the left, FIG. 3 shows in turn a slice having the thickness d at the time of excitation of the slice. In this embodiment of the disclosure, the excitation is unchanged compared with the prior art. Accordingly, in the simplified view, that is, both static spins 23 in the spinal cord and also dynamic CSF spins 21, which are located at the time of excitation in the slice having the thickness d, are again excited, that is, tilted into the transverse plane. Spins outside the slice are not excited. The thickness d of the slice is typically specified by the user and determines the resolution in the slice selection direction.

In the center, FIG. 3 shows the same slice at a time of the first refocusing RF pulse 2 that is half an echo t interval ES/2 later. In this embodiment, the nominal thickness of the slice that is captured by the refocusing RF pulse 2 is increased by a factor of 3 compared with the thickness d of the excitation slice that is generated by the excitation pulse 1. The inner vertical dotted lines define the region of the refocusing slice that has been captured by the excitation pulse. This region is referred to hereafter as the “inner slice” or “inner slice having the thickness d”. The static spins 23 in the spinal cord in this region are captured by the excitation pulse 1 and by the refocusing RF pulse 2, such that they transmit a signal portion to the echoes focused later. Spinal cord spins outside this region continue to fail to transmit a signal portion due to the lack of excitation. On the other hand, a change occurs in the flowing CSF spins. The CSF spins 25, which were located at the time of excitation in the inner slice having the thickness d and which had left the inner slice between excitation and the first refocusing RF pulse 2, are captured in spite of this by the broadened refocusing RF pulse 2 and therefore transmit a signal portion in the echoes focused later, insofar as they are not flowing so fast that they also leave the (in Example 3d broad) region that is captured by the refocusing RF pulses 2. CSF spins 24, which were not located at the time of excitation in the inner slice having the thickness d, continue to fail to provide a signal portion due to the lack of excitation, such that the resolution in the slice-selection direction remains unchanged and is determined by the thickness d of the excitation slice (specified by the user).

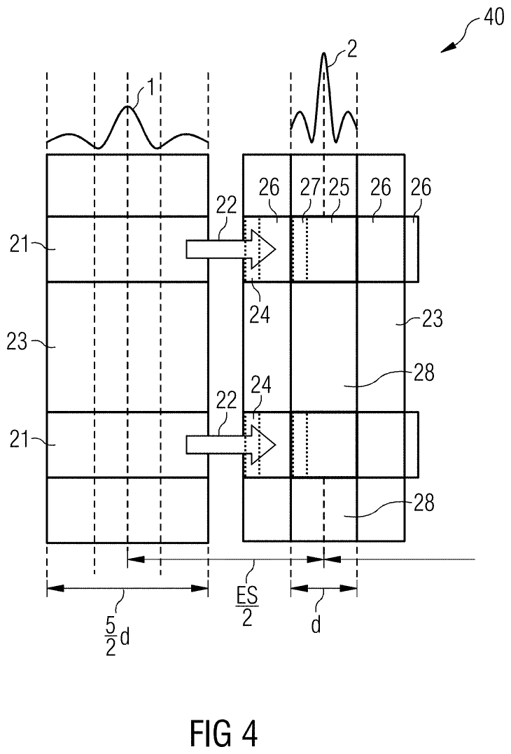

FIG. 4 illustrates a spin echo pulse sequence 40, which forms part of an embodiment of the method according to the disclosure. With this pulse sequence 40, “time-of-flight loss” can be avoided or significantly reduced. In this embodiment, instead of the refocusing slice, the excitation slice is broadened by a factor of x compared with the desired width d specified by the user, whilst the width of the refocusing slice remains unchanged compared with the prior art. On the left of FIG. 4, a slice having the width x×d is excited, with x having the value 2.5 in the figure. In the simplified view, therefore, both static spins 23 of the spinal cord and also dynamic CSF spins 21, which at the time of excitation are located in the slice with the thickness x×d, are excited, that is, tilted into the transverse plane. Spins outside the slice are not excited. Here, the thickness of the excitation slice is broadened by a factor of x compared with the thickness d typically specified by the user. On the right-hand side, FIG. 4 shows the same slice at a time of the refocusing RF pulse 2a that is a half echo t interval ES/2 later. In this embodiment of the sequence according to the disclosure 40, the nominal thickness d of the slice that is captured by the refocusing RF pulse 2 remains unchanged compared with the prior art, that is, is equal to the user specification d. In spite of this, an “outer slice”, the width of which is equal to the excitation slice, that is, x×d (x=5/2), is additionally drawn. The static spins 28 in the spinal cord that are located inside the inner slice having the width d are captured by the excitation pulse 1 and the refocusing RF pulse 2, such that they transmit a signal portion to the later focused echo. Static spinal cord spins 23, which are located outside this region having the thickness d, but inside the outer slice having the thickness x×d are indeed excited but do not transmit a signal portion due to the lack of refocusing. A change compared with the prior art occurs in turn in the case of the CSF spins 21. The CSF spins 27, which newly flow into the inner slice having the width d in the time interval between excitation and the first refocusing RF pulse 2 and which were located at the time of excitation in the broader region captured by the excitation pulse 1, have been excited and refocused and therefore transmit a signal portion in the later focused echoes 3. CSF spins 24, which at the time of excitation were not located in the slice with the thickness 2.5 d, continue to fail to transmit a signal portion due to the lack of excitation.

“New” CSF spins, which flow so fast that at the time of excitation they were located outside the outer slice captured by the excitation pulse 1, do not provide a signal portion (not drawn). CSF spins 26, which at the time of refocusing were not located in the inner slice having the thickness d, do not provide a signal portion due to the lack of refocusing, such that the resolution in the slice selection direction is determined for static and dynamic spins by the thickness d (specified by the user). The variant shown in FIG. 4 functions only with one single refocusing, since with repeated refocusing, the CSF signal of spins for the second echo that leaves the thin refocusing slice in the time between the first and second refocusing RF pulse is lost.

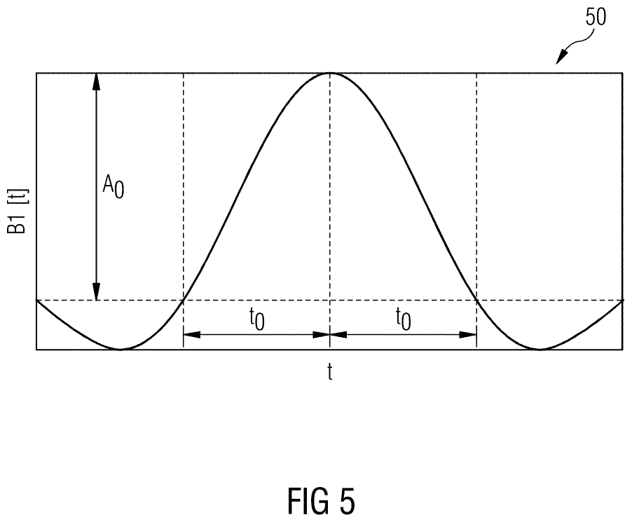

FIG. 5 shows a diagram of an enveloping sinc-function of an RF pulse.

It should be mentioned that “time-of-flight loss” is not the only physical effect that leads to loss of the CSF signal. A further important cause of signal losses can be turbulent flow. In turbo spin echo technology, turbulent flow leads to stimulated spins and spin-echoes acquiring a different phase and therefore not being able to be constructively superimposed. This can lead to signal loss and even to complete signal obliteration. The effect can be reduced insofar as the main flow direction coincides with the slice selection direction, as in the axial imaging of the spinal cord, by nulling the first gradient moment in the slice selection direction chronologically in the middle of the refocusing RF pulses. Such gradient schemes are known in the prior art by the keywords “Gradient Moment Nulling” or flow- or velocity-compensated gradient schemes and are described in the article “Gradient Moment Nulling in Fast Spin Echo” by R. Scott Hink and Todd Constable, published in the journal MRM 32: pages 698-706 (1994). In this sense, the sequence drawn in FIG. 1 is flow-compensated. The gradient schemes that allow the first and the nulled gradient moment to assume the value 0 at the time of the refocusing RF pulses can only completely compensate for the effect where there is uniform flow and constant velocity, however. The flow of CSF pulsates with the heart rate, however, and is therefore not uniform. In spite of this, a combination of the method according to the disclosure with such a flow-compensated gradient scheme in the slice selection direction at the time of the refocusing RF pulses is recommended. Furthermore, TSE gradient schemes are known which enable the first moment in the slice selection direction to additionally assume the value 0 at the time of the echoes, that is, during the readout interval (not drawn).

Furthermore, a combination of such gradient schemes with the broadening according to the disclosure of the excitation or refocusing RF pulses is possible and advantageous. Gradient schemes that are compensated to a higher order than the first can theoretically also compensate for even a more complex flow but in practice are not significant due to the increased time required and the extension of the echo interval that this necessitates.

A further effect that can reduce the CSF signal and which is also not compensated for by the method according to the disclosure can occur in a multislice sequence in which adjacent slices have been excited in a common TR interval (the repetition time TR indicates the time between two excitation pulses) when CSF spins that have already been saturated in an earlier excitation flow into an adjacent slice. These spins provide a reduced signal portion due to the long T1-time for CSF in the focused echoes. This effect can only be avoided by acquiring the slices successively, that is, the acquisition of a second slice does not begin until the data for the first slice has been acquired in its entirety, and so on. Such an acquisition scheme is not acceptable time-wise in clinical practice, however.

In connection with the present disclosure, due to the broadening of the excitation pulse or of the refocusing RF pulses, what is known as a nested acquisition scheme is necessary to avoid crosstalk or overlap of the slices. A nested acquisition scheme is understood here to mean an acquisition scheme in which the slices to be acquired are subdivided into sub-sets that are acquired successively. With two sub-sets, for example, at first only the even slices are acquired, and the acquisition of the odd slices is started only when the even slices have been acquired in their entirety. Here, the number given to the slice corresponds to its anatomical position. That is, the slice number of a slice is increased or decreased in relation to the slice directly spatially adjacent thereto. A subdivision into two sub-sets therefore doubles the effective interval between slices. A similar system applies to the subdivision into three or more sub-sets. Nested acquisition schemes are optionally selectable on modern MR units. On Siemens scanners, for example, the number of sub-sets desired can be set as “Concatenations”. On Philips scanners, the equivalent parameter is called “packages”. A slice selection is achieved by applying an amplitude-modulated RF pulse (for example, with a SINC-shaped envelope) simultaneously with a slice selection gradient. A characteristic value of the selective RF pulse is its RF-bandwidth Δf, which indicates the band of frequencies that the RF pulse contains.

The amplitude of the slice selection gradient G_{z} is selected as a function of the RF bandwidth such that a slice of the desired thickness is excited or refocused:

$$d = \frac{Δ f}{( \frac{γ}{2 π} ) {G}_{z}} \qquad ( 3 )$$

where γ/2π is the gyromagnetic ratio and for hydrogen protons is 42.576 MHz/T.

The technically easiest method to increase the thickness d of the refocusing slice by a factor of x therefore consists in reducing the amplitude of the slice selection gradient G_{z} by a factor of x where the shape and duration of the RF pulse remain unchanged.

This procedure has a disadvantage, however. The resonance frequency of the MR unit suffers local interference with the introduction of the human body. Although attempts are made to compensate for this interference by applying additional fields (known as patient-specific shimming), this is not entirely successful by a long way for the region of the human neck that is of particular interest in the context of the present disclosure. It is the case on the other hand that the resonance frequency in the examination region can primarily vary by several hundred hertz in the foot-head direction and in particular at higher field strengths.

The location of the slice excitation is set perpendicular to the slice selection gradient by an appropriate selection of the carrier frequency f_{RF} of the RF pulse:

$${f}_{R F} = \frac{γ}{2 π} ( {B}_{0} + \vec{{G}_{z} \cdot } \vec{r} ) = {f}_{0} + \frac{γ}{2 π} \cdot \vec{{G}_{z}} \cdot \vec{r} . \qquad ( 4 )$$

Here \vec{G_{z}} is the slice selection gradient, \vec{r} a vector that points from the isocenter of the MR unit to the desired location of slice excitation and “⋅” is the scalar product of the two vectors. Therefore, the carrier frequency f_{RF} depends on the desired distance z₀ of the slice from the isocenter in the direction of the slice selection gradient

$${z}_{0} = \frac{\vec{{G}_{z}} \cdot \vec{r}}{\vert \vec{{G}_{z}} \vert} = \frac{\vec{{G}_{z}} \cdot \vec{r}}{{G}_{z}} . \qquad ( 5 )$$

When calculating the carrier frequency, one assumes a constant in what is known as the frequency adjusted patient-specifically measured resonance frequency f₀ in the MR unit. Now if the frequency differs by δf from f₀, then the slice is accordingly displaced by δz compared with the desired interval z₀ in the direction of the slice selection gradient

$$δz = ( \frac{2 π}{γ} ) \frac{δ f}{{G}_{z}} . \qquad ( 6 )$$

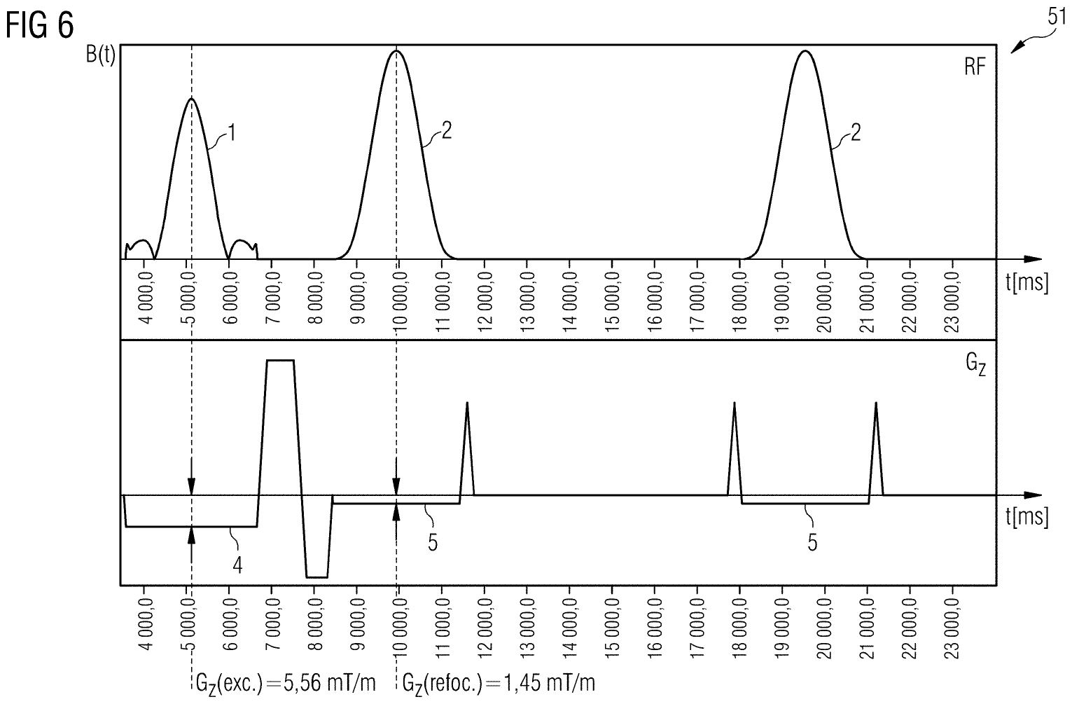

It now follows from formula 6 that reducing the slice selection gradient of the RF pulse by a factor of x increases this deviation by a factor of x. In particular (and that is the real problem), insofar as, for example, one now reduces the slice selection gradient of the refocusing RF pulses, the displacement of the refocusing-slice in the direction of the slice selection gradient no longer concurs with the displacement of the excitation slice. Such a decrease in the slice selection gradient is illustrated in FIG. 6.

FIG. 6 shows an extract 51 of a pulse diagram with RF pulses 1, 2 shown in a first line and slice selection gradients 4, 5 shown in a second line. First an excitation RF pulse 1 is applied and synchronous with this, a slice selection gradient with a relatively high amplitude of 5.56 mT/m. After a half echo time, a refocusing RF pulse is generated and synchronous with this a slice selection gradient 5 with a clearly lower amplitude of 1.45 mT/m. As a result of the gradient 5 being clearly weaker than the first gradient 4, a “broadening” of the refocusing RF pulse occurs, as a result of which a thicker slice is refocused.

Depending on the bandwidth of the RF pulses and the size of the local off-resonance δf, this can lead to the excited slice and the refocused slice no longer or only partly overlapping. Since there is no overlap, no echo signals are generated even for static spins and this results in a total loss of signal. Where there is a partial overlap, the effective slice thickness corresponds to the overlap region and the lost signal increases in proportion with the reduction in the effective slice thickness.

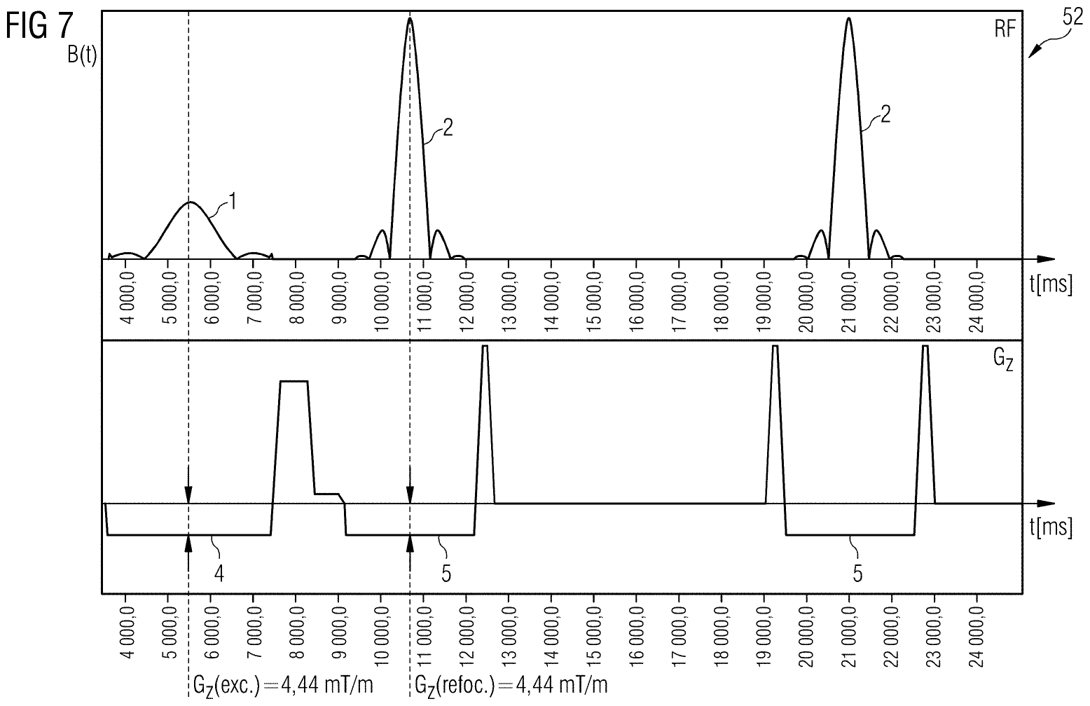

In order to avoid this, in an exemplary embodiment of the disclosure, it is not the slice selection gradient of the broader RF pulse that is reduced when the shape of the pulse remains unchanged, but the envelope of the RF pulse or the duration of the RF pulse is altered such that the RF bandwidth of the broader RF pulse increases by a factor of x. According to equation 3, the width d of the refocusing RF pulse therefore increases by a factor of x, as long as the amplitude of the relevant slice selection gradient is left unchanged. Assuming that in the original sequence the excitation pulse and the refocusing RF pulse have an approximately identical amplitude, the off-resonance insensitivity of the sequence is maintained. Such a procedure is illustrated in FIG. 7.

FIG. 7 shows an extract 52 of a pulse diagram with RF pulses 1, 2 shown in a first line and slice selection gradients 4, 5 shown in a second line. Unlike the illustration 51 shown in FIG. 6, in the pulse sequence shown in FIG. 7 there ensues an increase in the slice thickness through an increase in the bandwidth. Unlike the situation with the pulse sequence shown in FIG. 6, the amplitude of the slice selection gradients 4, 5 remains unchanged at a relatively high 4.44 mT/m.

One method of increasing the bandwidth of an RF pulse by a factor of x is to shorten the duration thereof by a factor of x whilst the envelope remains unaltered. A further possibility with the method shown in FIG. 7 consists in increasing what is known as the bandwidth-time product of the pulse by a factor of x whilst the duration of the pulse remains unchanged. Here the dimensionless bandwidth-time product is defined as the product from the duration of the pulse and its RF bandwidth. Altering the bandwidth-time product typically changes the envelope of the RF pulse.

This can be explained in greater detail using the example of a SINC pulse:

The time-dependence of the envelope of a SINC pulse is:

$${B}_{1} ( t ) = \{ \begin{matrix}{A}_{0} SIN C ( \frac{π t}{{t}_{0}} ) = {A}_{0} sin ( \frac{πt}{{t}_{0}} ) & - {N}_{L} {t}_{0} \leq t \leq {N}_{R} {t}_{0} \\ 0 & else\end{matrix} . \qquad ( 7 )$$

Here A₀ is the peak amplitude of the RF pulse at the time t=0, to is the duration of the half central peak and N_{L} or N_{R} is the number of zero points to the left or right of the central peak.

Hence the duration T of the RF pulse is:

T=(N_{L}+N_{R})t₀. (8)

The bandwidth δf an SINC pulse is given in a good approximation by

$$Δ f = \frac{1}{{t}_{0}} . \qquad ( 9 )$$

For the dimensionless time bandwidth time product, the following therefore applies:

$$Δ f T = \frac{1}{{t}_{0}} ( {N}_{L} + {N}_{R} ) {t}_{0} = ( {N}_{L} + {N}_{R} ) \qquad ( 10 )$$

FIG. 5 shows the envelope of a SINC pulse with N_{L}=N_{R}=2.

Shortening the duration T of the RF pulse according to the disclosure by a factor of x is therefore equivalent to shortening t₀ by a factor of x where the number of zero points N_{L} and N_{R} remains unchanged. According to equation 9, the bandwidth therefore increases by a factor of x.

The increase shown in FIG. 7 in the time-bandwidth product by a factor of x (in FIG. 7 by a factor of 3) whilst the duration T remains unchanged therefore corresponds to a shortening of t₀ by a factor of x with a simultaneous increase in the number of zero points (N_{L}+N_{R}) by a factor of x, such that the duration T remains unchanged.

Of course, any interim solution is also possible, that is, a partial shortening of the RF pulses and an increase of the time-bandwidth product. In this variant the only crucial factor is that the amplitude of the slice selection gradients of excitation and refocusing RF pulses is approximately equal in order to achieve an off-resonance insensitivity of the sequence.

The increasing according to the disclosure of the time-bandwidth product has the additional advantage that the slice profile is typically improved as a result thereof, which leads to a reduction in crosstalk across the slices. A good slice profile makes it possible to restrict the necessary number of combinations.

The amplitude of the slice selection gradients of excitation and refocusing RF pulses is often selected as not exactly equal in order to avoid what is known as a third-arm artifact. In Siemens sequences the amplitudes typically differ by at least 20%. An increased off-resonance sensitivity of the sequence is therefore taken into account. It therefore makes sense to only require the slice selection gradients to have “approximately” the same amplitude.

When using identical SINC pulses for excitation and refocusing, the slice profile of the refocusing RF pulse is narrowed compared with the slice profile of the excitation pulse as a result of the higher flip angle. To compensate for this, one reduces the amplitude of the slice selection gradient, in Siemens sequences for example, by an empirical factor of 1,2. This is not to be confused with the broadening according to the disclosure of the refocusing RF pulse, in order to avoid or reduce a flow artifact. With the broadening according to the disclosure, the width of the slice profile is increased, that is, the FWHM (full width at half maximum) is increased. The factor 1.2 in the prior art merely has the effect of the width of the slice profile of the excitation pulse and the refocusing pulse being approximately equal with regard to the full width at half maximum.

It is known from the prior art that a broadening of the slice thickness reduces the “time of flight loss” effect. This means the broadening of excitation and refocusing RF pulses, such as they can typically be adjusted via the user interface of the MR unit. This procedure is linked to a corresponding reduction in the resolution in the slice selection direction. The broadening according to the disclosure of only one of the two pulses does not on the other hand influence the resolution of the sequence.

Furthermore, it should be mentioned that the amplitude of the slice selection gradient that is applied during the irradiation of the excitation pulse or of the refocusing RF pulse is not necessarily constant during the irradiation. In imaging using turbo spin echo sequences, often what are known as variable-rate pulses are used to reduce the amount of RF output absorbed by the patient. For this purpose, the RF amplitude is reduced in the vicinity of the peak of the RF pulse. Then the amplitude of the slice selection gradient also has to be reduced accordingly. Approximately the same amplitude of the slice selection gradients of the excitation pulse and the refocusing RF pulse is understood, where variable-rate pulses are used, to mean approximately equal amplitudes of the selection gradients in the vicinity of the peak of the respective RF pulse.

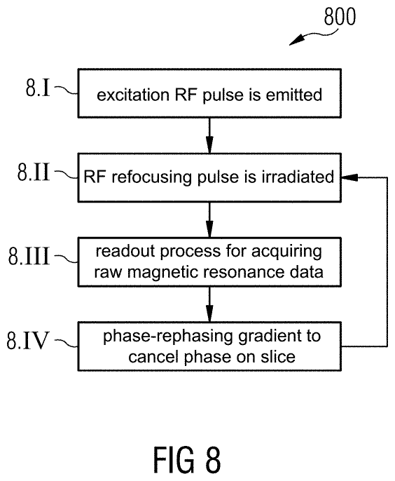

FIG. 8 shows a flow diagram 800 with which a method for activating a magnetic resonance imaging system for generating magnetic resonance imaging data BD relating to an examination subject P is illustrated according to an exemplary embodiment of the disclosure. In the method, a turbo spin echo sequence is used. First, in step 8.I, an excitation RF pulse is emitted. The effective area of the excitation RF pulse is restricted here with the aid of a slice selection gradient to a slice with a specified thickness d.

Furthermore, in step 8.II, after a half echo time ES/2 after excitation, a refocusing step ensues, in which an RF refocusing pulse is irradiated, with which a refocusing region is influenced. The refocusing pulse serves the purpose of reversing a dephasing process that ensues after excitation and affects the transverse magnetization. The width of the refocusing region is determined via the bandwidth of the refocusing RF pulse and the amplitude of the slice selection gradient. These are selected such that the width of the slice captured by the refocusing RF pulse is greater than the slice thickness d. This means that the refocusing acts on a thicker slice than the excitation. Since the excited spins have changed position due to the motion of the cerebrospinal fluid after a half echo time and hence have partly left the excitation slice, a broadening of the refocusing slice has the effect of also refocusing those CSF spins that have indeed left the excitation slice but are still located in the broader slice captured by the refocusing RF pulse. They therefore transmit a signal portion to the readout signal.

The spatial information for each slice is encoded in a 2-dimensional k-space data matrix. In the example of Cartesian imaging using a turbo spin echo sequence, one k-space line is filled in with each echo, for example.

After an echo time ES after the excitation process, the readout process for acquiring raw magnetic resonance data ensues in step 8.III. In the readout process, HF signals are captured from both the excited and refocused spins. For this purpose, the signal is encoded by a readout gradient in the readout direction with a frequency by means of which a spatial resolution of the slice to be read out is encoded in the readout direction, and is imprinted by a phase-encoding-gradient in the phase direction with a phase by means of which encoding of the slice to be read out is achieved in the phase-encoding direction. The readout direction and the phase direction are oriented orthogonal to the slice direction. Furthermore, in step 8.IV, the phase that has been imprinted on the slice to be read out is cancelled again with the aid of a phase-rephasing gradient.

Next there is a return to step 8.II and there ensues a fresh refocusing of the slice and in step 8.III a fresh readout, wherein by changing the phase that has been imprinted, a different k-space line in the k-space matrix of the slice to be read out is encoded and the corresponding signal is read out. Steps 8.II to 8.IV are repeated a plurality of times. Therefore a plurality of k-space lines are read out after an excitation. As a result, the scanning time can be reduced compared, for example, with a spin echo sequence, in which only one single k-space line is read out per excitation.

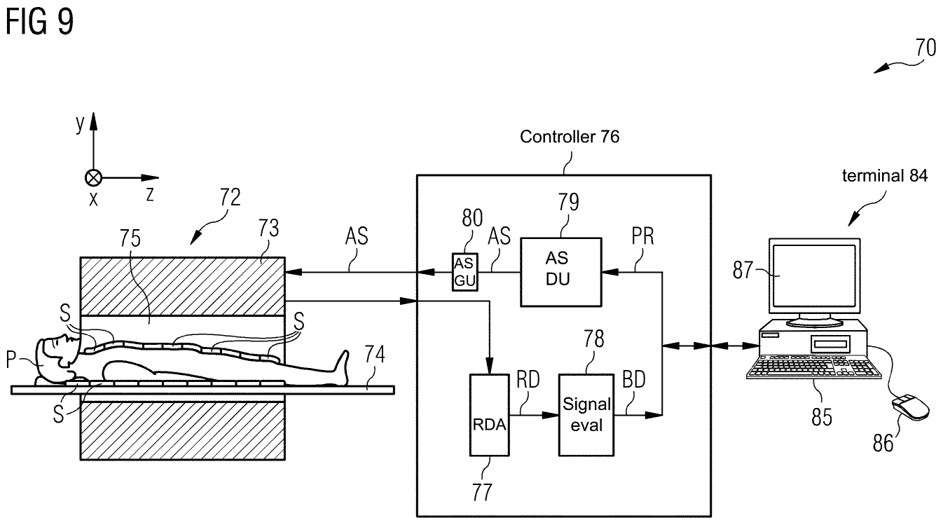

FIG. 9 shows an exemplary embodiment of a magnetic resonance unit according to the disclosure 70, which is capable of working in accordance with the method according to the disclosure. The core component of this magnetic resonance unit 70 is the magnetic resonance scanner (also known as MR tomograph) 72 itself, in which a patient P is positioned on a patient-positioning table 74 (also known as patient couch 74) in an annular main field magnet 73, which encloses the scanning area 75. On and optionally under the patient, a multiplicity of local coils S, also known as magnetic resonance coils, are located, for example. In an exemplary embodiment, the scanner 72 (and/or one or more of its components) includes processor circuitry that is configured to perform one or more functions and/or operations of the scanner 72 (or of the respective component(s)).

The patient couch 74 is slidable in a longitudinal direction, that is, along the longitudinal axis of the scanner 72. This direction is denoted as the z-direction in the spatial coordinate system that is likewise shown. Inside the main field magnet a whole-body coil, not shown in greater detail, is located in the scanner 72, with which coil high-frequency pulses can be transmitted and received. Furthermore, the scanner 72 comprises in the usual manner, not shown in FIG. 9, gradient coils, in order to be able to apply a magnetic field gradient in all the spatial directions x, y, z.

The scanner 72 is activated by a controller 76, which is shown separately here. A terminal 84 is connected to the controller 76. This terminal 84 has a screen 87, a keyboard 85 and a pointing device 86 for a graphic user interface, for instance a mouse 86 or suchlike. In an exemplary embodiment, the terminal 84 is a computer or the like. The terminal 84 serves among other things as a user interface via which an operator operates the controller 76 and hence the scanner 72. Both the controller 76 and the terminal 84 can also be an integral component of the scanner 72. In an exemplary embodiment, the controller 76 (and/or one or more of its components) includes processor circuitry that is configured to perform one or more functions and/or operations of the controller 76 (or of the respective component(s)).

The magnetic resonance system 71 can in addition to this also comprise all the usual further components or features of such systems, such as, for example, interfaces for connecting to a communications network, for example, an image information system or suchlike. All these components are not shown in FIG. 9, however, in order to improve clarity.

Via the terminal 84, an operator can communicate with the controller 76 and thus ensure that the desired measurements are carried out, by for example the scanner 72 being activated by the controller 76 such that the required high-frequency pulse sequences are transmitted by the high-frequency coils and the gradient coils are connected in an appropriate manner. Via the controller 76, raw data RD emanating from the scanner and required for imaging is also acquired. For this purpose, the controller 76 comprises a raw data acquisition unit 77, in which the measurement signals emanating from the scanner 72 are converted into raw data RD. This is achieved, for example, by means of a demodulation and subsequent digitization of the measured signals. In a signal evaluation unit (signal evaluator) 78, which can be, for example, a module of the controller 76, raw data RD is reconstructed into image data BD. The image data BD can be visualized, for example, on the screen/display 87 of the terminal 84 and/or deposited in a memory or transmitted via a network. To perform the method according to the disclosure, the controller 76 has an activation sequence-determination unit (activation sequence determiner) 79, with which an activation sequence AS is determined, which includes, for example, the pulse sequence 30 shown in FIG. 3. For example, the activation sequence-determination unit 79 receives from the terminal 84 protocol data PR, which have pre-set parameter values for a pulse sequence 30 that is to be determined. Furthermore, the controller 76 also comprises an activation sequence-generation unit 80, which is configured to run an activation sequence AS, including the pulse sequence according to the disclosure 30, on the magnetic resonance scanner 72, such that the method according to the disclosure for activating a magnetic resonance imaging system for generating magnetic resonance imaging data BD relating to an examination subject P is carried out.

The components required for implementing the disclosure in a magnetic resonance system 71, such as the raw data acquisition unit 77, the signal evaluation unit 78, the activation sequence determination unit 79 or the activation sequence generation unit 80 can be at least partly or even completely provided in the form of software components. Conventional magnetic resonance systems already have programmable controllers, such that in this way, one or more exemplary embodiment of the disclosure may be carried out with the aid of appropriate control software. This means that a corresponding computer program is loaded directly into the memory of a programmable controller 76 of the respective magnetic resonance system 71, which program has program coding means to perform the method according to the disclosure. In this way, already existing magnetic resonance systems can be upgraded in a simple and cost-effective manner.

In particular it is possible that some of the components present in the controller 76 have already been implemented as sub-routines or that existing components are also used for the purpose according to the disclosure. This affects, for example, the activation sequence determination unit 79, which can be implemented, for example, in an activation sequence-generation unit that is already provided in an existing controller 76, which unit is intended to activate the high-frequency coils, gradient coils or other components in the scanner in an appropriate manner to carry out a conventional imaging measurement.

Finally, it is once again pointed out that the method, pulse sequences and devices described in the aforementioned are merely exemplary embodiments of the disclosure and that the disclosure can be varied by a person skilled in the art without departing from the scope of the disclosure insofar as it is set out in the claims. For the sake of completeness, it is also pointed out that the use of the indefinite article “a” or “an” does not preclude the relevant features from being present in plurality. Likewise, the term “unit” does not preclude this from consisting of a plurality of components that can optionally also be spatially distributed.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

For the purposes of this discussion, the term “processor circuitry” shall be understood to be circuit(s), processor(s), logic, or a combination thereof. A circuit includes an analog circuit, a digital circuit, state machine logic, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for activating a magnetic resonance imaging (MRI) system for generating MRI data relating to an examination subject, in which system raw magnetic resonance (MR) data is captured, having at least one spin echo or turbo spin echo pulse sequence, the method comprising:
emitting a radio frequency (RF) excitation pulse to excite a region that contains a region to be imaged, the excited region being defined by a selection gradient;
emitting an RF refocusing pulse to influence a refocusing region, the refocusing region at least partly including the region to be imaged, and being defined by at least one selection gradient; and
receiving high-frequency (HF) signals to acquire raw MR data, wherein a spatial extent of the excitation region is selected to be different from a spatial extent of the refocusing region.

2. The method as claimed in claim 1, wherein the spatial extent of the refocusing region is selected to be greater than the spatial extent of the excitation region.

3. The method as claimed in claim 1, wherein when the method includes a spin echo sequence, the spatial extent of the excitation region is selected to be greater than the spatial extent of the refocusing region.

4. The method as claimed in claim 1, wherein:
the excited region includes an excitation slice that is defined by a slice selection gradient and the refocusing region includes a refocusing slice that is defined by a slice selection gradient; and
a spatial slice thickness of the excitation slice is selected to be different from a slice thickness of the refocusing slice.

5. The method as claimed in claim 4, wherein the refocusing slice is selected to be thicker than the excitation slice.

6. The method as claimed in claim 4, wherein when the method includes a spin echo sequence, the excitation slice is selected to be thicker than the refocusing slice.

7. The method as claimed in claim 4, wherein a thickness of a thinner of the excitation and refocusing slices is equal to a slice thickness specified by the user.

8. The method as claimed in claim 4, wherein one or more pulse parameters of the excitation pulse and/or of the refocusing pulse are adjusted such that the slice selection gradients of both the excitation and refocusing pulses have a same amplitude.

9. The method as claimed in claim 4, wherein the one or more pulse parameter of a broader RF pulse of the excitation and refocusing pulses are adjusted such that the slice selection gradients of both the excitation and refocusing pulses have approximately a same amplitude.

10. The method as claimed in claim 4, wherein a gradient scheme is selected in a slice selection direction, a first moment of which is equal to zero chronologically in a middle of the refocusing RF pulses.

11. The method as claimed in claim 10, wherein a gradient scheme is selected in the slice selection direction, the first moment of which is equal to zero during the acquisition of the raw MR data.

12. A computer program which includes a program and is directly loadable into a memory of a controller of the MRI system, when executed by the controller, causes the controller to perform the method as claimed in claim 1.

13. A non-transitory computer-readable storage medium with an executable program stored thereon, that when executed, instructs a processor to perform the method of claim 1.

14. A method for providing an activation sequence to activate a magnetic resonance imaging (MRI) system, the method comprising:
providing an RF excitation pulse to excite a region that contains a region to be imaged;
providing a first slice selection gradient to define the excited region;
providing an RF refocusing pulse to influence a refocusing region;
providing a second slice selection gradient to define the refocusing region;
providing a readout module to acquire raw magnetic resonance data, wherein a spatial extent of the excitation region is selected to be different from a spatial extent of the refocusing region.

15. A computer program which includes a program and is directly loadable into a memory of a controller of the MRI system, when executed by the controller, causes the controller to perform the method as claimed in claim 14.

16. A non-transitory computer-readable storage medium with an executable program stored thereon, that when executed, instructs a processor to perform the method of claim 14.

17. A magnetic resonance imaging (MRI) system, comprising:
a magnetic resonance (MR) scanner; and
a controller that is configured to control the MR scanner to:
emit a radio frequency (RF) excitation pulse to excite a region that contains a region to be imaged, the excited region being defined by a selection gradient;
emit an RF refocusing pulse to influence a refocusing region, the refocusing region at least partly including the region to be imaged, and being defined by at least one selection gradient; and
receive high-frequency (HF) signals to acquire raw MR data, wherein a spatial extent of the excitation region is selected to be different from a spatial extent of the refocusing region.
